(19) United States
(12) Patent Application Publication
(10) Pub. No.: US 2026/0231382 A1
(43) Pub. Date: Aug. 6, 2026

(54) VEHICLE CONTROL DEVICE

(71) Applicant: Astemo, Ltd., Chiyoda-ku, Tokyo (JP)

(72) Inventor: Tomoyuki TAKADA, Hitachinaka-shi, Ibaraki (JP)

(73) Assignee: Astemo, Ltd., Chiyoda-ku, Tokyo (JP)

(21) Appl. No.: 19/147,741

(22) PCT Filed: Jan. 27, 2023
(86) PCT No.: PCT/JP2023/002615

§ 371 Date: Jul. 14, 2025

(51) Int. Cl. H05K 9/00

(52) U.S. Cl. CPC H05K 9/0024

(57) ABSTRACT

The electronic control device includes a substrate, a protective member, a case, and a protruding part. The protective member is mounted between the electronic component and the connector on the substrate. The case includes a base and a cover. The protruding part is disposed at a position facing the protective member in the cover, and protrudes toward the substrate and the base. One of the protruding part and the protective member has a recessed part, and the other of the protruding part and the protective member is inserted into the recessed part. The protruding part and the protective member are arranged so as to overlap each other in an outward view from an internal space of the case.

### TECHNICAL FIELD

The present invention relates to an electronic control device.

### BACKGROUND ART

An electronic control device having an electronic component for controlling an automobile is disposed in the automobile. In recent years, demand for advanced driving assistance systems (hereinafter referred to as ADAS) and automatic driving (hereinafter referred to as AD) systems has increased, and the development of automatic driving technology for automobiles has accelerated. In order to realize a driving assistance system such as a collision damage reduction brake, automatic driving, and the like, an electronic control device mounted on a vehicle or the like is required to have high calculation performance. Therefore, an integrated circuit having a high operation frequency is built in the electronic control device. Along with this, radio frequency electromagnetic noise radiated by the electronic control device tends to increase, and it is necessary to suppress this to be equal to or less than a reference value defined by the law of each country.

As a technique for preventing such electromagnetic wave noise from leaking to the outside, for example, there is a technique as described in PTL 1. PTL 1 describes a technique including a main substrate, a connector disposed at a predetermined position on the main substrate, and a CPU disposed at a predetermined position on the main substrate. Further, PTL 1 describes that a conductive metal substrate disposed perpendicular to a plane of the main substrate is provided at a predetermined position between the connector of the main substrate and the CPU, and a bare chip is disposed on the metal substrate.

FIG. 9 is a cross-sectional view illustrating the conventional electronic control device.

As illustrated in FIG. 9, the conventional electronic control device 300 includes a substrate 101 on which an electronic component 104 such as a semiconductor component is mounted, a base 402 and a cover 401 forming a case, and a connector 102 mounted on the substrate 101. The cover 401 is provided with a protrusion 410 protruding toward the substrate 101. In addition, the metal substrate 505 is disposed perpendicular to the substrate 101 between the electronic component 104 and the connector 102 on the substrate 101.

### CITATION LIST

### Patent Literature

PTL 1: JP H9-223895 A

### SUMMARY OF INVENTION

### Technical Problem

However, in the conventional technique, a mechanical load is generated at the connection portion between the electronic substrate and the metal substrate due to vibration or the like. Therefore, in the case of the connection method in which the metal substrate is sandwiched by the clip lead, the metal substrate may be detached from the electronic substrate. In addition, in the case of the connection method using solder, there is a problem that solder cracks occur and electrical connection failure occurs.

Furthermore, in the conventional technique, it is difficult to dispose a metal substrate 505 perpendicularly to the substrate 101 in manufacturing. Therefore, it is necessary to widen the gap x between the metal substrate 505 and the protruding part 410 in order to avoid interference. As a result, the conventional technique has a problem that leakage of electromagnetic wave noise to the outside cannot be sufficiently reduced.

In consideration of the above problems, an object of the present invention is to provide an electronic control device capable of reducing leakage of electromagnetic wave noise to the outside of a case.

### Solution to Problem

In order to solve the above problems and achieve the object, an electronic control device includes a substrate on which an electronic component and a connector are mounted, a protective member, a case, and a protruding part. The protective member is mounted between the electronic component and the connector on the substrate. The case includes a base on which the substrate is placed and a cover that covers the base on which the substrate is placed. The protruding part is disposed at a position facing the protective member in the cover, and protrudes toward the substrate and the base. One of the protruding part and the protective member has a recessed part, and the other of the protruding part and the protective member is inserted into the recessed part. The protruding part and the protective member are arranged so as to overlap each other in an outward view from an internal space of the case.

### ADVANTAGEOUS EFFECTS OF INVENTION

According to the electronic control device having the above configuration, it is possible to reduce leakage of the electromagnetic wave noise to the outside of the case.

### BRIEF DESCRIPTION OF DRAWINGS

FIG. 1 is a perspective view illustrating a substrate of an electronic control device according to a first embodiment;

FIG. 2 is a cross-sectional view of the electronic control device according to the first embodiment.

FIG. 3 is an enlarged cross-sectional view illustrating a protruding part and a protective member of the electronic control device according to the first embodiment.

FIG. 4 is a perspective view illustrating a protective member of an electronic control device according to a second embodiment.

FIG. 5 is a perspective view illustrating a protective member of an electronic control device according to a third embodiment.

FIG. 6 is an enlarged cross-sectional view illustrating a protruding part and a protective member of an electronic control device according to a fourth embodiment.

FIG. 7 is an enlarged cross-sectional view illustrating a protruding part and a protective member of an electronic control device according to a fifth embodiment.

FIG. 8 is an enlarged cross-sectional view illustrating a protruding part and a protective member of an electronic control device according to a sixth embodiment.

FIG. 9 is a cross-sectional view illustrating a conventional electronic control device.

### DESCRIPTION OF EMBODIMENTS

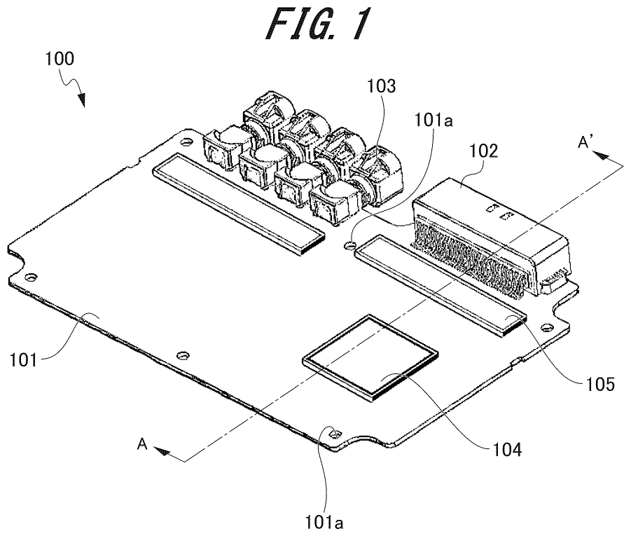

Hereinafter, embodiments of an electronic control device will be described with reference to FIGS. 1 to 8. In the drawings, the same members are denoted by the same reference numerals.

### 1. First Embodiment

First, a configuration of an electronic control device according to a first embodiment (hereinafter, it is referred to as “present example”) will be described with reference to FIGS. 1 to 3.

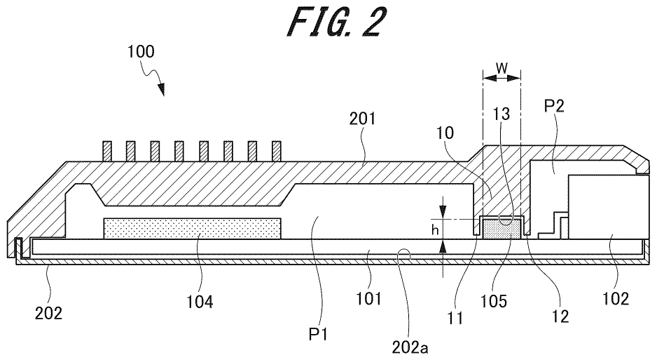

FIG. 1 is a plan view illustrating a substrate of the electronic control device, and FIG. 2 is a cross-sectional view illustrating the electronic control device.

The device illustrated in FIGS. 1 and 2 is an electronic control device mounted on an automobile and having an electronic circuit that controls the automobile. As illustrated in FIGS. 1 and 2, an electronic control device 100 includes a substrate 101 on which an electronic component 104 such as a semiconductor component is mounted, a base 202 and a cover 201 forming a case, connectors 102 and 103 mounted on the substrate 101, and two protective members 105. The substrate 101 is housed in the base 202 and the cover 201. Further, two protective members 105 are mounted on the substrate 101.

The substrate 101 is formed in a substantially flat plate shape. A plurality of fixing holes 101a are formed in the substrate 101. The substrate 101 is placed on one surface 202a of the base 202. The cover 201 is disposed so as to cover one surface of the base 202 on which the substrate 101 is placed. Then, the cover 201 is fixed to the base 202 by inserting a fixing screw into a fixing hole 101a provided in the substrate 101. Note that the base 202 and the cover 201 forming the case are made of a material having conductivity, and are made of, for example, metal or plated with a conductive resin or resin surface.

The connectors 102 and 103 are mounted on one end portion of the substrate 101. The protective member 105 is disposed between the connectors 102 and 103 mounted on substrate 101 and the electronic component 104. One of the two protective members 105 and 105 is disposed near the connector 102, and the remaining protective member 105 is disposed near the connector 103. A fixing hole 101a into which a fixing screw is inserted is formed between the two protective members 105 and 105 on the substrate 101.

The protective member 105 may be a conductive material or a material capable of absorbing electromagnetic waves. An example thereof includes a copper plate, a conductive resin, a plated resin surface, and a radio wave absorbing material. The protective member 105 is electrically connected to the base 202 through a land (not illustrated) of the substrate 101.

For example, the protective member 105 is formed in a substantially flat plate shape having a rectangular shape. As illustrated in FIG. 2, a length h of the protective member 105 in the height direction orthogonal to the mounting surface of the substrate 101 is set shorter than a length W of the protective member 105 in the width direction parallel to the mounting surface of the substrate 101 (W>h). That is, the protective member 105 is formed in a horizontally long shape.

The cover 201 forming the case covers the base 202 on which the substrate 101 is placed. A protruding part 10 is formed on the cover 201 at a position facing the protective member 105. The protruding part 10 protrudes from an inner wall surface of the cover 201 toward the substrate 101 and the base 202. The protruding part 10 partitions the internal space of the electronic control device 100 into a first space P1 on a side of the electronic component 104 and a second space P2 on a side of the connectors 102 and 103. A recessed part 13 is formed at a tip of the protruding part 10.

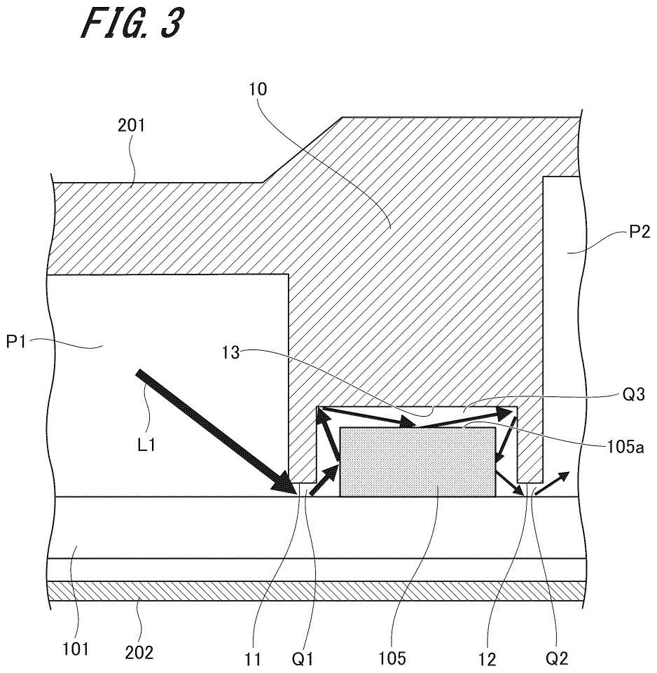

FIG. 3 is an enlarged sectional view illustrating the protruding part 10 and the protective member 105.

As illustrated in FIG. 3, the recessed part 13 is recessed parted in a direction away from the substrate 101 and the base 202 from the tip of the protruding part 10. The recessed part 13 is recessed in a substantially rectangular shape according to the shape of the protective member 105.

The protective members 105 mounted on the substrate 101 is inserted into the recessed part 13. A gap Q3 is formed between one surface 105a of the protective member 105 opposite to the mounting surface of the substrate 101 and the recessed part 13.

A first tip 11 on a side of the first space P1 and a second tip 12 on a side of the second space P2 are formed at the tip of the protruding part 10. The recessed part 13 is formed between the first tip 11 and the second tip 12. The first tip 11 is disposed closer to the first space P1 than the protective member 105, and the second tip 12 is disposed closer to the second space P2 than the protective member 105. A gap Q1 is formed between the first tip 11 and the substrate 101. Similarly, a gap Q2 is also formed between the second tip 12 and the substrate 101.

In addition, the first tip 11 and the second tip 12 are positioned closer to the substrate 101 than one surface 105a of the protective member 105 opposite to the mounting surface of the substrate 101. Therefore, when the internal space of the electronic control device 100 is viewed from a side of the first space P1 to the second space P2, the first tip 11 and the second tip 12 of the protruding part 10 and the protective member 105 overlap each other. Therefore, an electromagnetic wave noise L1 generated from the electronic component 104 can be blocked by the protruding part 10 and the protective member 105. As a result, the electromagnetic wave noise L1 from the electronic component 104 can be prevented from leaking out of the case, that is, leaking from the first space P1 to the second space P2. In addition, it is also possible to prevent the electromagnetic wave noise from the outside from entering the inside of the case, that is, entering from the second space P2 into the first space P1.

In particular, low-frequency noise is irregularly reflected as illustrated in FIG. 3 when passing through gaps Q1, Q2, and Q3 between the protruding part 10 and the protective member 105. Thus, the electromagnetic wave noise can be attenuated.

In addition, with respect to the radio frequency noise, the smaller the gaps Q1, Q2, and Q3 between the protruding part 10 and the protective member 105, and the longer the distance the noise passes through the gaps Q1, Q2, and Q3, the more the attenuation effect is. On the other hand, the protective member 105 and the tip of the protruding part 10 overlap each other at two positions on both sides of the first space P1 and the second space P2 of the protective member 105. Therefore, a distance through which the electromagnetic wave noise L1 passes can be increased, and an attenuation effect can be exhibited even for radio frequency noise.

In addition, the protective member 105 is formed in a rectangular flat plate shape, and it is not intended to mount electronic components on the protective member 105. Therefore, not only the shape of the protective member 105 but also the shape of the protruding part 10 covering protective member 105 can be made relatively simple in manufacturing. As a result, the gaps Q1, Q2, and Q3 between the protective member 105 and the protruding part 10 can be narrowed, and radio frequency noise can be further attenuated.

Since the gaps Q1, Q2, and Q3 are provided between the protective member 105 and the protruding part 10, heat generated in the first space P1 in the case can be released from the gaps Q1, Q2, and Q3 toward the second space P2. As a result, according to the electronic control device 100 of the present example, not only the electromagnetic wave noise countermeasure but also the heat dissipation effect can be enhanced.

Furthermore, in a case where the protective member 105 and the protruding part 10 are brought into contact with each other, it is not only necessary to process the cover 201 as a case with high accuracy, but also the substrate 101 and the protruding part 10 expand and contract due to temperature change or vibration, and contact and non-contact states are repeated, which causes distortion of the substrate 101. On the other hand, by providing the gaps Q1, Q2, and Q3 between the protective member 105 and the protruding part 10, not only the design of the cover 201 can be facilitated, but also the cover 201 can be easily assembled.

Further, the gaps Q1, Q2, and Q3 between the protective member 105 and the protruding part 10 may be filled with a conductive adhesive. This makes it possible to improve countermeasures against electromagnetic wave noise. In addition, it is preferable to dispose the adhesives at intervals in order to maintain the heat-proof effect.

Furthermore, leakage of electromagnetic wave noise can be prevented without providing a special electromagnetic wave noise countermeasure component such as an EMI gasket or an on-board contact. As a result, durability can be improved, and costs of an EMI gasket, an on-board contact, and the like can be reduced.

As illustrated in FIG. 1, the fixing screw for fixing the cover 201 is inserted between two protective members 105, 105. Therefore, the electromagnetic wave noise leaking from the gap between the two protective members 105 and 105 is blocked by the fixing screw and the cover 201.

### 2. Second Embodiment

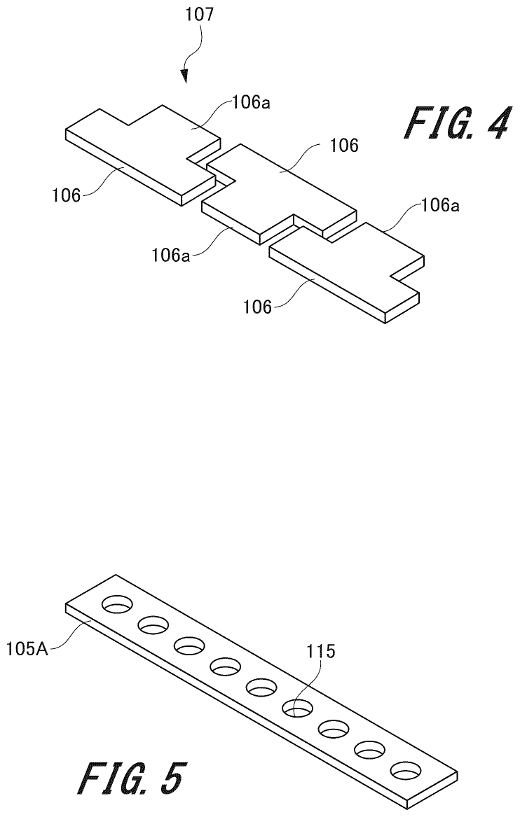

Next, an electronic control device according to a second embodiment will be described with reference to FIG. 4.

FIG. 4 is a perspective view illustrating a protective member of the electronic control device according to the second embodiment;

The electronic control device according to the second embodiment is different from the electronic control device 100 according to the first embodiment in the shape of a protective member. Therefore, here, a protective member will be described, and a part common to the electronic control device 100 according to the first embodiment will be denoted by one reference numeral, and redundant description will be omitted.

As illustrated in FIG. 4, a protective member 107 is divided into a plurality of blocks 106 having a substantially T-shape. In addition, the blocks 106 are mounted such that a convex part 106a is parallel to the mounting surface of the substrate 101. Further, the plurality of blocks 106 are arranged such that the directions of the convex parts 106a are opposite to the convex parts 106a of the adjacent blocks 106. Therefore, the plurality of blocks 106106 are mounted such that the directions of the convex parts 106a are staggered.

By dividing the protective member 107 into the small blocks 106 in this manner, the protective member can be handled as a reel product similarly to other electronic components. As a result, the blocks 106 can be mounted using a chip mounter, and the settlement efficiency can be increased. Furthermore, the heat capacity per block 106 can be lower than that of the protective member 105 according to the first embodiment. As a result, the solder is easily melted, and the mountability is also improved.

Furthermore, as illustrated in FIG. 4, by alternately mounting the directions of the convex parts 106a of the blocks 106, the plurality of blocks 106 are arranged to overlap each other when the second space P2 is viewed from the first space of the case. As a result, the electromagnetic wave noise that tries to pass through the gap between the plurality of blocks 106 can be diffusely reflected by the block 106. Further, the length of the gap between the first space P1 and the second space P2 between the two blocks 106 can be increased. As a result, the electromagnetic wave noise passing between the two blocks 106 can be attenuated, and the electromagnetic wave noise can be prevented from leaking from the inside of the case to the outside. Note that noise from the outside can also be prevented from entering the case. from outside of case to inside and outside

Since other configurations are similar to those of the electronic control device 100 according to the first embodiment, the description thereof will be omitted. The electronic control device including such the protective member 107 can also obtain the same operation and effect as those of the electronic control device 100 according to the first embodiment described above.

### 3. Third Embodiment

Next, an electronic control device according to a third embodiment will be described with reference to FIG. 5.

FIG. 5 is a perspective view illustrating a protective member of the electronic control device according to the third embodiment;

The electronic control device according to the third embodiment is different from the electronic control device 100 according to the first embodiment in the shape of a protective member. Therefore, here, a protective member will be described, and a part common to the electronic control device 100 according to the first embodiment will be denoted by one reference numeral, and redundant description will be omitted.

As illustrated in FIG. 5, a protective member 105A is formed in a substantially flat plate shape. A plurality of fixing holes 115 are formed in the protective member 105A. Providing the holes 115 can reduce the heat capacity of the entire protective member 105A. As a result, it is possible to suppress occurrence of a problem that the solder is hardly melted during the reflow process.

Since other configurations are similar to those of the electronic control device 100 according to the first embodiment, the description thereof will be omitted. The electronic control device including such the protective member 105A can also obtain the same operation and effect as those of the electronic control device 100 according to the first embodiment described above.

### 4. Fourth Embodiment

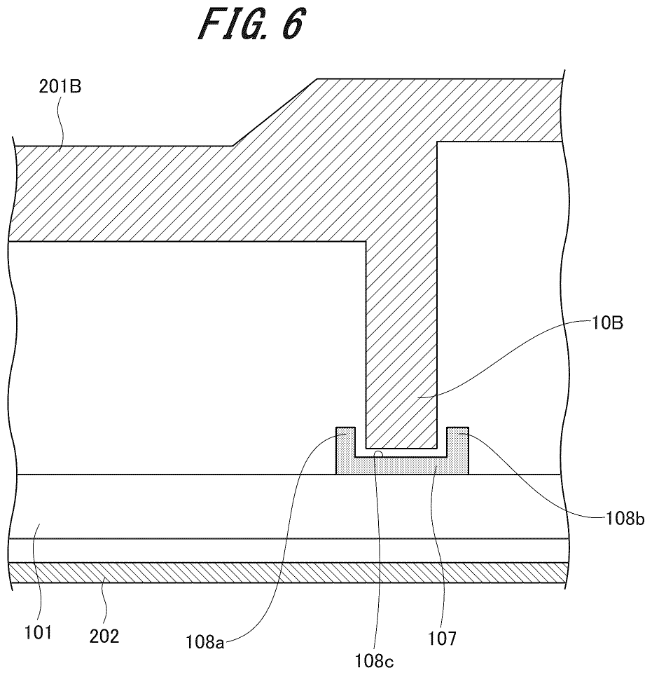

Next, an electronic control device according to a fourth embodiment will be described with reference to FIG. 6.

FIG. 6 is a cross-sectional view illustrating a protruding part and a protective member of the electronic control device according to the fourth embodiment.

The electronic control device according to the third embodiment is different from the electronic control device 100 according to the first embodiment in the shapes of the protruding part and the protective member. Therefore, here, a protective member will be described, and a part common to the electronic control device 100 according to the first embodiment will be denoted by one reference numeral, and redundant description will be omitted.

As illustrated in FIG. 6, a protective member 108 is mounted on the substrate 101. In addition, a protruding part 10B is formed at a position facing the protective member 108 in a cover 201B forming the case. The protruding part 10B protrudes from the inner wall surface of the cover 201 toward the substrate 101 and the base 202. In addition, no recessed part is formed at the tip of the protruding part 10B according to the fourth embodiment.

The protective member 108 has a U-shaped cross section. A recessed part 108c is formed on one surface of the protective member 108 facing the protruding part 10B. The recessed part 108c is recessed parted from one surface of the protective member 108 toward the substrate 101 and the base 202. The tip of the protruding part 10B is inserted into the recessed part 108c.

On one surface of the protective member 108, a first tip 108a and a second tip 108b are formed with the recessed part 108c interposed therebetween. The first tip 108a is formed on a side of the first space P1, and the second tip 108b is formed on a side of the second space P2.

The first tip 108a and the second tip 108b are disposed at positions farther from the substrate 101 than the tip of the protruding part 10B. Therefore, in a case where it is desired to view the internal space of the case of the electronic control device from the side of the first space P1 to the side of the second space P2 (outside), the tip of the protruding part 10B and the first tip 108a and the second tip 108b of the protective member 108 overlap each other.

In addition, although an example in which the recessed part 108c is provided in the protective member 108 has been described, the present invention is not limited thereto. For example, the protective member 108 may be divided into the first tip 108a and the second tip 108b.

Since other configurations are similar to those of the electronic control device 100 according to the first embodiment, the description thereof will be omitted. The electronic control device including such the protective member 108 and the protruding part 10B can also obtain the same operation and effect as those of the electronic control device 100 according to the first embodiment described above.

As shown in the electronic control device according to the first embodiment and the electronic control device according to the fourth embodiment, a recessed part may be formed in one of the protruding part and the protective member, and the other of the protruding part and the protective member may be inserted into the recessed part.

### 5. Fifth Embodiment

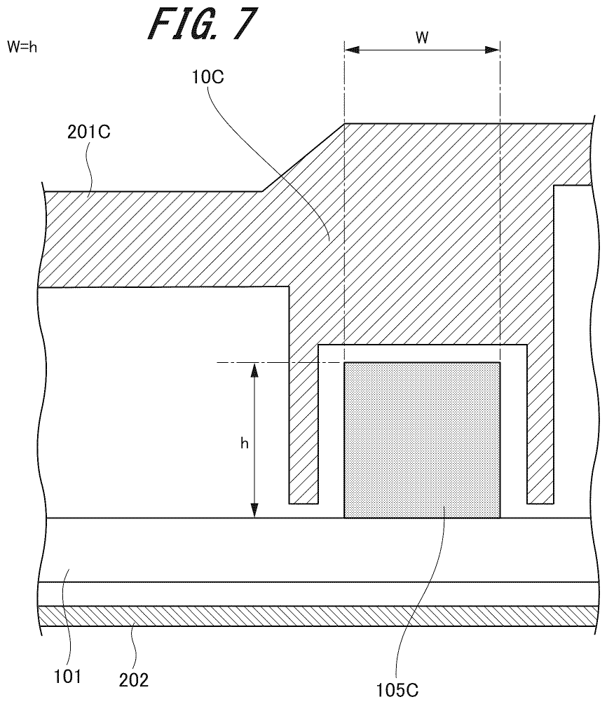

Next, an electronic control device according to a fifth embodiment will be described with reference to FIG. 7.

FIG. 7 is a cross-sectional view illustrating a protruding part and a protective member of the electronic control device according to the fifth embodiment.

The electronic control device according to the fifth embodiment is different from the electronic control device 100 according to the first embodiment in dimensions of a protective member. Therefore, here, a protective member will be described, and a part common to the electronic control device 100 according to the first embodiment will be denoted by one reference numeral, and redundant description will be omitted.

As illustrated in FIG. 7, a length h of a protective member 105C in the height direction orthogonal to the mounting surface of the substrate 101 is set equal to a length W of the protective member 105C in the width direction parallel to the mounting surface of the substrate 101 (W=h). That is, the protective member 105C has a square cross-sectional shape. Note that a protruding part 10C is formed on a cover 201C. A recessed part corresponding to the dimension of the protective member 105C is formed at the tip of the protruding part 10C.

Since other configurations are similar to those of the electronic control device 100 according to the first embodiment, the description thereof will be omitted. The electronic control device including such the protective member 105C and the protruding part 10C can also obtain the same operation and effect as those of the electronic control device 100 according to the first embodiment described above.

### 6. Sixth Embodiment

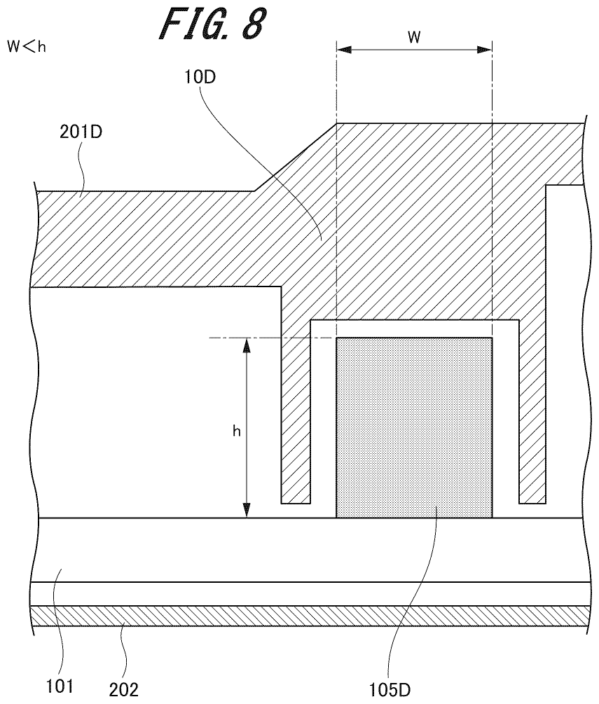

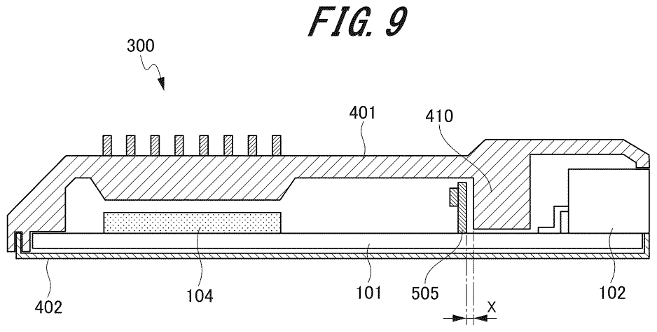

Next, an electronic control device according to a sixth embodiment will be described with reference to FIG. 8.

FIG. 8 is a cross-sectional view illustrating a protruding part and a protective member of the electronic control device according to the sixth embodiment.

The electronic control device according to the sixth embodiment is different from the electronic control device 100 according to the first embodiment in dimensions of a protective member. Therefore, here, a protective member will be described, and a part common to the electronic control device 100 according to the first embodiment will be denoted by one reference numeral, and redundant description will be omitted.

As illustrated in FIG. 7, a length h of a protective member 105D in the height direction orthogonal to the mounting surface of the substrate 101 is set to be longer than a length W of the protective member 105D in the width direction parallel to the mounting surface of the substrate 101 (W<h), that is, the protective member 105D is formed to have a vertically long cross-sectional shape. Note that a protruding part 10D is formed on a cover 201D. A recessed part corresponding to the dimension of the protective member 105D is formed at the tip of the protruding part 10D.

Since other configurations are similar to those of the electronic control device 100 according to the first embodiment, the description thereof will be omitted. The electronic control device including such the protective member 105D and the protruding part 10D can also obtain the same operation and effect as those of the electronic control device 100 according to the first embodiment described above.

Note that, a member having a horizontally long cross-sectional shape as the protective member 105 according to the first embodiment can be disposed perpendicular to the substrate 101 as compared with a vertically long member illustrated in the protective member 105D according to the sixth embodiment. Further, horizontally long protective member 105 shown in the first embodiment can improve vibration resistance more than vertically long protective member 105D shown in the sixth embodiment.

Note that the present invention is not limited to the embodiments described above and illustrated in the drawings, and various modifications can be made without departing from the gist of the invention described in the claims. In addition, a part of the configuration of a certain embodiment can be replaced with the configuration of another embodiment, and the configuration of another embodiment can be added to the configuration of a certain embodiment. Furthermore, it is possible to add, delete, and replace other configurations for a part of the configuration of another embodiment.

In the present specification, words such as “parallel” and “orthogonal” are used, but these do not strictly mean only “parallel” and “orthogonal”, and may be in a state of “substantially parallel” or “substantially orthogonal” including “parallel” and “orthogonal” and in a range in which the function can be exhibited.

### REFERENCE SIGNS LIST

10, 10B, 10C, 10D protruding part
11 first tip
12 second tip
13 recessed part
100 electronic control device
101 substrate
101a fixing hole
102, 103 connector
104 electronic component
105, 105A, 105C, 105D, 107, 108 protective member
105a one surface
106 block
106a convex part
107 protective member
108a first tip
108b second tip
108c recessed part
115 hole
201, 201B, 2010, 201D cover (case)
202 base (case)
L1 electromagnetic wave noise
P1 first space
P2 second space
Q1, Q2, Q3 gap

1. An electronic control device comprising:
a substrate on which an electronic component and a connector are mounted;
a protective member mounted between the electronic component and the connector on the substrate;
a case including a base on which the substrate is placed and a cover that covers the base on which the substrate is placed; and
a protruding part disposed at a position facing the protective member in the cover and protruding toward the substrate and the base,
wherein one of the protruding part and the protective member has a recessed part, and
an other of the protruding part and the protective member is inserted into the recessed part, and
the protruding part and the protective member are arranged to overlap each other in an outward view from an internal space of the case.

2. The electronic control device according to claim 1, wherein
the protruding part has a recessed part at a tip, and
the protective member is inserted into the recessed part of the protruding part.

3. The electronic control device according to claim 1,
wherein the protective member is formed as being divided into a plurality of blocks.

4. The electronic control device according to claim 3, wherein
the block is formed in a T-shape, and a convex part thereof is disposed in parallel with a mounting surface of the substrate,
the plurality of blocks are arranged such that directions of convex parts are alternately arranged, and
the plurality of the blocks are arranged to overlap each other in the outward view from the internal space of the case.

5. The electronic control device according to claim 1,
wherein the protective member has a plurality of holes.

6. The electronic control device according to claim 1, wherein one surface of the protective member facing the protruding part has a recessed part, and
a front tip of the protruding part is inserted into the recessed part of the protective member.

7. The electronic control device according to claim 1,
wherein the protective member is formed of a conductive material or a material capable of absorbing an electromagnetic wave.

8. The electronic control device according to claim 1, wherein a length of the protective member in a height direction orthogonal to a mounting surface of the substrate is set shorter than a length of the protective member in a width direction parallel to the mounting surface of the substrate.
